(19) United States
(12) Patent Application Publication
(10) Pub. No.: US 2025/0259870 A1
(43) Pub. Date: Aug. 14, 2025

(54) PROCESSING DEVICE AND PROCESSING METHOD

(71) Applicant: DISCO CORPORATION, Tokyo (JP)

(72) Inventors: Kotaro ABE, Tokyo (JP); Yusuke KAJIHARA, Tokyo (JP); Hiroshi MAEDA, Tokyo (JP)

(21) Appl. No.: 19/045,809

(22) Filed: Feb. 5, 2025

(30) Foreign Application Priority Data
Feb. 14, 2024 (JP) 2024-020532

(51) Int. Cl. H01L 21/67; H01L 21/66; H01L 21/78

(52) U.S. Cl. CPC H01L 21/67288; H01L 21/67092; H01L 21/78; H01L 22/12

(57) ABSTRACT

A processing device for processing a workpiece includes: a holding table that holds the workpiece; a processing unit that performs processing on the workpiece held on the holding table; an abnormality detection unit that detects an abnormality of the workpiece; and a control unit that controls at least the processing unit and the abnormality detection unit. The control unit includes: a registration unit that registers first reference information serving as a reference for determining that the workpiece before processing is normal; and a comparison unit that compares the first reference information registered in the registration unit with first detection information obtained by detecting the workpiece by the abnormality detection unit before the workpiece is processed by the processing unit.

### CROSS-REFERENCE TO RELATED APPLICATION(S)

The present application claims priority to and incorporates by reference the entire contents of Japanese Patent Application No. 2024-020532 filed in Japan on Feb. 14, 2024.

### BACKGROUND

The present disclosure relates to a processing device and a processing method for processing a workpiece.

A plurality of devices are formed on a front surface of a thin plate-shaped wafer and then the wafer is divided into individual devices, so that device chips to be mounted on electronic devices can be formed. For dividing a workpiece such as a wafer, for example, a processing device is used, such as a cutting device capable of cutting the workpiece with an annular cutting blade or a laser processing device that irradiates the workpiece with a laser beam to process the workpiece. In the processing device, the workpiece is processed under predetermined processing conditions in order to obtain a predetermined processing result.

However, the workpiece may not be appropriately processed by the processing device due to a defect of the processing device or the like. Then, when manufacturing is performed in a state where a scratch is generated on the workpiece or the chip or in a state where contamination (waste) adheres to the workpiece or the chip, the obtained chip may become a defective product.

Therefore, in order to confirm that the processing of the workpiece has been appropriately performed, the workpiece processed by the processing device is imaged and inspected by a camera unit (see, for example, JP 2021-32588 A).

However, when a scratch or contamination is found in the workpiece during the inspection as described in JP 2021-32588 A, the cause is not limited to a processing defect of the processing device, and may be a scratch already formed on the workpiece or contamination adhering to the workpiece before processing. In such a case, there is a problem that it takes time to specify the cause.

Therefore, concerning a processing device for processing a workpiece, there is a need for specifying whether an abnormality of a front surface of a workpiece is caused by a defect of the processing device.

### SUMMARY

A processing device according the present disclosure is a device for processing a workpiece. The processing device includes: a holding table that holds the workpiece; a processing unit that performs processing on the workpiece held on the holding table; an abnormality detection unit that detects an abnormality of the workpiece; and a control unit that controls at least the processing unit and the abnormality detection unit. The control unit includes: a registration unit that registers first reference information serving as a reference for determining that the workpiece before processing is normal; and a comparison unit that compares the first reference information registered in the registration unit with first detection information obtained by detecting the workpiece by the abnormality detection unit before the workpiece is processed by the processing unit.

A processing method according to the present disclosure is a method for processing a workpiece. The processing method includes: holding the workpiece on a holding table; performing processing on the workpiece held on the holding table by a processing unit; detecting an abnormality of the workpiece before performing the processing; and before performing the processing and after detecting the abnormality of the workpiece, comparing reference information registered for determining that the workpiece before processing is normal with detection information obtained by newly detecting the workpiece in detecting the abnormality.

### BRIEF DESCRIPTION OF THE DRAWINGS

FIG. 1 is a perspective view illustrating a configuration example of a processing device according to a first embodiment;

FIG. 2 is a diagram illustrating an example of a first reference image registered in a registration unit of a control unit of the processing device illustrated in FIG. 1;

FIG. 3 is a diagram illustrating an example of a second reference image registered in the registration unit of the control unit of the processing device illustrated in FIG. 1;

FIG. 4 is a flowchart illustrating a part of a flow of a processing method according to the first embodiment;

FIG. 5 is a flowchart illustrating the other part of the flow of the processing method according to the first embodiment;

FIG. 6 is a diagram illustrating an example of a first comparison image generated in a first imaging step of the processing method illustrated in FIG. 4;

FIG. 7 is a diagram illustrating an example of a second comparison image generated in a second imaging step of the processing method illustrated in FIG. 5;

FIG. 8 is a diagram illustrating an example of a first reference image registered in a registration unit of a control unit of the processing device according to the second embodiment;

FIG. 9 is a diagram illustrating another example of a first reference image registered in the registration unit of the control unit of the processing device according to the second embodiment;

FIG. 10 is a diagram illustrating an example of a second reference image registered in the registration unit of the control unit of the processing device according to the second embodiment;

FIG. 11 is a diagram illustrating another example of a second reference image registered in the registration unit of the control unit of the processing device according to the second embodiment;

FIG. 12 is a diagram illustrating an example of a first comparison image generated in a first imaging step according to the second embodiment;

FIG. 13 is a diagram illustrating an example of a second comparison image generated in a second imaging step of the processing method according to the second embodiment; and

FIG. 14 is a perspective view illustrating a modification of the processing device illustrated in FIG. 1.

### DETAILED DESCRIPTION

Embodiments of the present disclosure will be described in detail with reference to the drawings. The present invention is not limited by the contents described in the following embodiments. In addition, the components described below include those that can be easily conceived by those skilled in the art and those that are substantially the same. Furthermore, the configurations described below can be appropriately combined. In addition, various omissions, substitutions, or changes can be made to the configurations without departing from the gist of the present invention.

### First Embodiment

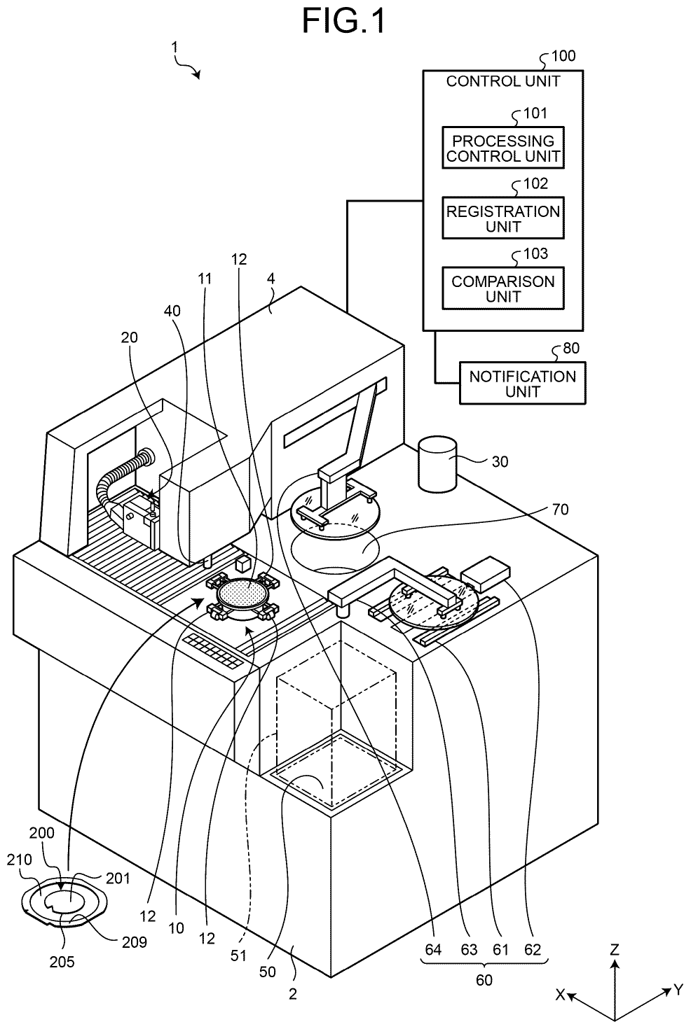

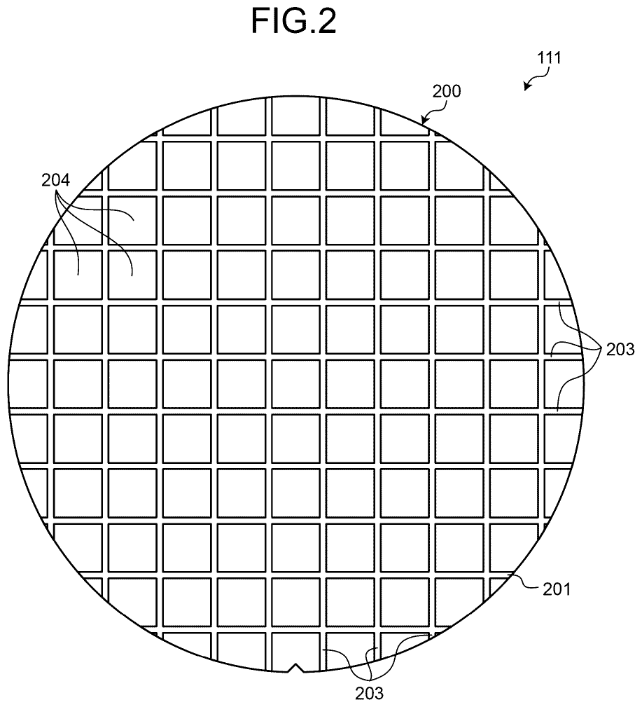

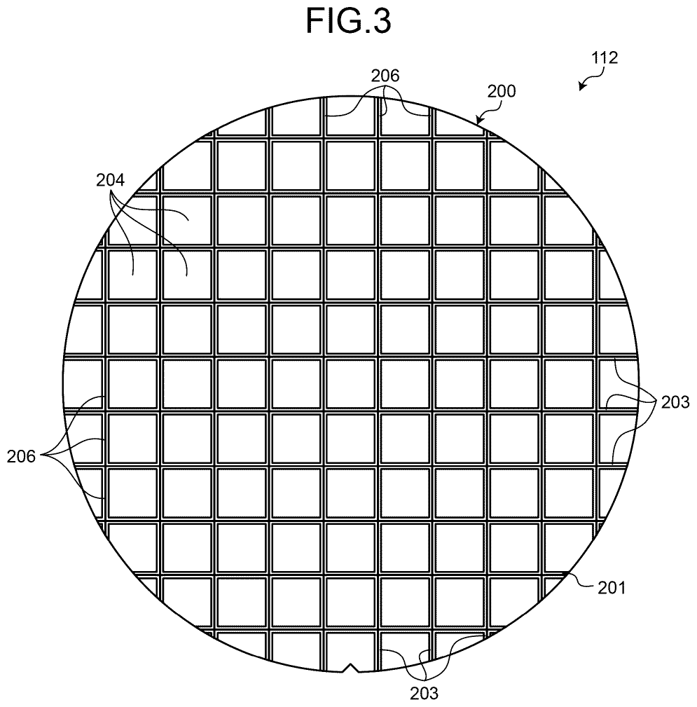

A processing device according to a first embodiment of the present invention will be described with reference to the drawings. FIG. 1 is a perspective view illustrating a configuration example of the processing device according to the first embodiment. FIG. 2 is a diagram illustrating an example of a first reference image registered in a registration unit of a control unit of the processing device illustrated in FIG. 1. FIG. 3 is a diagram illustrating an example of a second reference image registered in the registration unit of the control unit of the processing device illustrated in FIG. 1.

### Workpiece

A processing device 1 according to the first embodiment is a cutting device that performs cutting processing (corresponding to processing) on a workpiece 200. In the first embodiment, the workpiece 200 is a disk-shaped semiconductor wafer using silicon, sapphire, gallium nitride, gallium arsenide, or the like as a base material, or a wafer such as an optical device wafer.

As illustrated in FIG. 2, in the workpiece 200, devices 204 are formed in regions divided in a lattice shape along a plurality of planned division lines 203 having the lattice shape on a front surface 201. The device 204 is, for example, an integrated circuit such as an integrated circuit (IC) or a large scale integration (LSI), or an image sensor such as a charge coupled device (CCD) or a complementary metal oxide semiconductor (CMOS), or a memory (semiconductor storage device).

In the first embodiment, a central portion of a tape 210 having a larger diameter than the workpiece 200 is attached to a back surface 205 on a back side of the front surface 201 of the workpiece 200. An annular frame 209 is attached to an outer edge of the tape 210. The workpiece 200 is supported in an opening inside the frame 209.

### Processing Device

The processing device 1 illustrated in FIG. 1 is a cutting device that holds the workpiece 200 on a holding table 10, performs cutting processing on the planned division lines 203 of the workpiece 200 with a cutting blade (not illustrated) to form cut grooves 206 along the planned division lines 203, and divides the workpiece 200 into individual devices 204. As illustrated in FIG. 1, the processing device 1 includes a holding table 10 (corresponding to a suction table) that sucks and holds the workpiece 200 on a holding surface 11, a cutting unit 20 that performs cutting processing on the workpiece 200 held by the holding table 10 with the cutting blade, a camera 30 serving as an abnormality detection unit that detects an abnormality of the workpiece 200, an alignment camera 40 that captures an image of the workpiece 200 held on the holding table 10, and a control unit 100.

In addition, the processing device 1 includes a moving unit (not illustrated) that moves the cutting unit 20 relative to the workpiece 200 held by the holding table 10. The moving unit includes an X-axis moving unit that feeds the holding table 10 for processing in an X-axis direction parallel to a horizontal direction, a Y-axis moving unit that feeds the cutting unit 20 for indexing in a Y-axis direction parallel to the horizontal direction and orthogonal to the X-axis direction, a Z-axis moving unit that feeds the cutting unit 20 for cutting in a Z-axis direction parallel to a vertical direction orthogonal to both the X-axis direction and the Y-axis direction, and a rotary moving unit that rotates the holding table 10 about an axis parallel to the Z-axis direction.

The X-axis moving unit relatively feeds the holding table 10 and the cutting unit 20 for processing along the X-axis direction by moving the holding table 10 in the X-axis direction, which is a feeding direction for processing. The Y-axis moving unit relatively feeds the holding table 10 and the cutting unit 20 for indexing along the Y-axis direction by moving the cutting unit 20 in the Y-axis direction, which is a feeding direction for indexing. The Z-axis moving unit relatively feeds the holding table 10 and the cutting unit 20 for cutting along the Z-axis direction by moving the cutting unit 20 in the Z-axis direction, which is a feeding direction for cutting.

Each of the X-axis moving unit, the Y-axis moving unit, and the Z-axis moving unit includes a known ball screw provided to be rotatable about an axis thereof, a known motor that rotates the ball screw about the axis, and a known guide rail that supports the holding table 10 or the cutting unit 20 in a movable manner in the X-axis direction, the Y-axis direction, or the Z-axis direction. The rotary moving unit includes a motor that rotates the holding table 10 about the axis.

The holding table 10 has a disk shape. The holding surface 11 that holds the workpiece 200 is formed of porous ceramic or the like. The holding table 10 is provided to be movable in the X-axis direction by the X-axis moving unit between a processing region below the cutting unit 20 and a loading/unloading region that is separated from below the cutting unit 20 to load/unload the workpiece 200, and is provided to be rotatable about the axis parallel to the Z-axis direction by the rotary moving unit.

The holding surface 11 is connected to a suction source (not illustrated) and is sucked by the suction source, so that the holding table 10 sucks and holds the workpiece 200 placed on the holding surface 11. In the first embodiment, the holding table 10 sucks and holds the back surface 205 side of the workpiece 200. The holding table 10 has a plurality of clamp portions 12 that clamps the frame 209 on an outer periphery of the holding surface 11.

The cutting unit 20 is a processing unit that performs cutting processing on the workpiece 200 held by the holding table 10. The cutting unit 20 is provided to be movable in the Y-axis direction by the Y-axis moving unit and movable in the Z-axis direction by the Z-axis moving unit with respect to the workpiece 200 held on the holding table 10.

The cutting unit 20 is provided on a gate-shaped support frame erected from a device body 2 via the Y-axis moving unit, the Z-axis moving unit, and so on. The cutting unit 20 is configured to locate the cutting blade at any position on the holding surface 11 of the holding table 10 by the Y-axis moving unit and the Z-axis moving unit.

The cutting unit 20 includes: a cutting blade that performs cutting processing on the workpiece 200; a spindle housing provided to be movable in the Y-axis direction and the Z-axis direction by the Y-axis moving unit and the Z-axis moving unit; a spindle provided to be rotatable about an axis thereof in the spindle housing; and a spindle motor (not illustrated) that rotates the spindle about the axis.

The cutting blade is an ultrathin cutting grindstone having a substantially ring shape, and performs cutting processing on the workpiece 200 along the planned division lines 203 of the workpiece 200 held by the holding table 10. In the first embodiment, the cutting blade includes an annular cutting edge that performs cutting processing on the workpiece 200, and an annular base that supports the cutting edge at an outer edge thereof and is detachably attached to the spindle.

The cutting edge is made of abrasive grains such as diamond or cubic boron nitride (CBN) and a bonding material such as metal or resin, and is formed to have a predetermined thickness. In the present invention, the cutting blade may be a so-called washer blade including only the cutting edge.

The spindle housing is supported to be movable in the Z-axis direction by the Z-axis moving unit, and movable in the Y-axis direction by the Y-axis moving unit via the Z-axis moving unit. The spindle housing houses a portion excluding a tip portion of the spindle, the spindle motor (not illustrated), and so on, and supports the spindle to be rotatable about the axis.

The spindle fixes the cutting blade to a tip thereof. The spindle is rotated by the spindle motor (not illustrated), and the tip portion of the spindle protrudes beyond a tip surface of the spindle housing. The tip portion of the spindle is formed to be gradually thinner toward the tip, and the cutting blade is fixed to the tip.

The axes of the spindle and the cutting blade of the cutting unit 20 are set parallel to the Y-axis direction.

In the first embodiment, the alignment camera 40 is fixed to a fixed frame 4 provided on the device body 2, and is disposed between the loading/unloading region and the processing region. The alignment camera 40 includes an imaging element that captures an image of a region to be divided of the workpiece 200 before cutting processing held on the holding table 10, that is, a part of the front surface 201 of the workpiece 200. The imaging element is, for example, a charge-coupled device (CCD) imaging element or a complementary MOS (CMOS) imaging element. The alignment camera 40 captures an image of the workpiece 200 held on the holding table 10, obtains an image for performing alignment to align the workpiece 200 and the cutting blade, and outputs the obtained image to the control unit 100.

Note that, in the first embodiment, in the image captured and obtained by the alignment camera 40, intensities of light received by respective pixels of the imaging element are defined by grayscales at plural stages (for example, 256 stages). That is, the image captured and acquired by the alignment camera 40 is an image showing intensities of light at stages corresponding to the intensities of light received by the pixels, that is, a grayscale image having shades of gray.

The processing device 1 includes an X-axis direction position detection unit (not illustrated) for detecting a position of the holding table 10 in the X-axis direction, a Y-axis direction position detection unit (not illustrated) for detecting a position of the cutting unit 20 in the Y-axis direction, and a Z-axis direction position detection unit for detecting a position of the cutting unit 20 in the Z-axis direction. Each of the X-axis direction position detection unit and the Y-axis direction position detection unit may include a linear scale parallel to the X-axis direction or the Y-axis direction and a reading head. The Z-axis direction position detection unit detects the position of the cutting unit 20 in the Z-axis direction based on a pulse of the motor. The X-axis direction position detection unit, the Y-axis direction position detection unit, and the Z-axis direction position detection unit output the positions of the holding table 10 in the X-axis direction and the cutting unit 20 in the Y-axis direction and the Z-axis direction to the control unit 100. In the first embodiment, the positions of the components of the processing device 1 in the X-axis direction, the Y-axis direction, and the Z-axis direction are determined based on predetermined reference positions (not illustrated). The reference position in the Z-axis direction is a position of the cutting unit 20 where a lower end of the cutting edge of the cutting blade is located on the same plane as the holding surface 11.

The processing device 1 includes: a cassette table 50 on which a cassette 51 containing the workpiece 200 before and after cutting processing is placed and which moves the cassette 51 in the Z-axis direction; a conveyance unit 60 which conveys the workpiece 200 between the cassette 51 and the holding table 10; and a cleaning unit 70 which cleans the workpiece 200 after cutting processing.

The conveyance unit 60 conveys the workpiece 200 from the cassette 51 placed on the cassette table 50 to the holding table 10 and the cleaning unit 70 in this order. The conveyance unit 60 includes: a pair of guide rails 61 on which the workpiece 200 taken out of the cassette 51 before cutting processing and the workpiece 200 accommodated in the cassette 51 after cutting processing are placed; a loading/unloading unit 62 that takes out the workpiece 200 before cutting processing from the cassette 51 and places the workpiece 200 on the guide rails 61, and accommodates the workpiece 200 after cutting processing on the guide rails 61 in the cassette 51; a first conveyance unit 63 that conveys the workpiece 200 before cutting processing on the guide rails 61 to the holding table 10 in the loading/unloading region and conveys the workpiece 200 after cleaning from the cleaning unit 70 onto the guide rails 61; and a second conveyance unit 64 that conveys the workpiece 200 after cutting processing from the holding table 10 in the loading/unloading region to the cleaning unit 70.

The guide rails 61 and the holding table 10 in the loading/unloading region constitute a conveyance path of the workpiece 200 conveyed from the cassette 51 to the holding table 10 by the conveyance unit 60.

The camera 30 detects an abnormality of the workpiece 200. The camera 30 images the workpiece 200. In the first embodiment, the camera 30 is disposed above the guide rails 61 in the Z-axis direction, and is provided on the conveyance path of the workpiece 200. The camera 30 includes an imaging element that captures an image of the entire front surface 201 of the workpiece 200 placed on the guide rails 61 before cutting processing. The imaging element is, for example, a charge-coupled device (CCD) imaging element or a complementary MOS (CMOS) imaging element. The camera 30 captures an image of the workpiece 200 placed on the guide rails 61 and outputs the obtained image to the control unit 100.

Note that, in the first embodiment, in the image captured and obtained by the camera 30, intensities of light received by respective pixels of the imaging element are defined by grayscales at plural stages (for example, 256 stages). That is, the image captured and acquired by the camera 30 is an image showing intensities of light at stages corresponding to the intensities of light received by the pixels, that is, a grayscale image having shades of gray.

The control unit 100 controls each component of the processing device 1 to cause the processing device 1 to perform a cutting processing operation on the workpiece 200. That is, the control unit 100 controls at least the holding table 10, the cutting unit 20, the cleaning unit 70, and the camera 30. Note that the control unit 100 is a computer including an arithmetic processing device including a microprocessor such as a central processing unit (CPU), a storage device including a memory such as a read only memory (ROM) or a random access memory (RAM), and an input/output interface device. The arithmetic processing device of the control unit 100 performs arithmetic processing according to a computer program stored in the storage device, and outputs a control signal for controlling the processing device 1 to each component of the processing device 1 via the input/output interface device.

The processing device 1 is connected to a display unit including a liquid crystal display device that displays a state of a processing operation, an image, and so on, an input unit used when an operator registers processing conditions and the like, and a notification unit 80. The display unit, the input unit, and the notification unit 80 are connected to the control unit 100. The input unit includes at least one of a touch panel provided on the display unit or an external input device such as a keyboard. The notification unit 80 emits at least one of sound or light to notify the operator. In the first embodiment, the function of the notification unit 80 is implemented by a screen displayed on the display unit, a warning light that emits light or the like, transmission of information to a mobile terminal held by the operator, or the like.

In addition, the control unit 100 includes a processing control unit 101, a registration unit 102, and a comparison unit 103. The processing control unit 101 controls each component of the processing device 1 to cause the processing device 1 to perform a cutting processing operation on the workpiece 200.

The registration unit 102 registers a first reference image 111 illustrated in FIG. 2 and a second reference image 112 illustrated in FIG. 3. The first reference image 111 is an image serving as a reference for determining that the workpiece 200 before cutting processing is normal, and the first reference image 111 is an image obtained by capturing an image of the entire front surface 201 of the workpiece 200 that is normal before the cutting processing with the camera 30. The normal workpiece 200 refers to a workpiece 200 that has no foreign matter such as contamination attached to the front surface 201 and has no scratch on the front surface 201.

The second reference image 112 is an image serving as a reference for determining that the workpiece 200 is normal after cutting processing, and the second reference image 112 is an image obtained by capturing an image of the entire front surface 201 of the workpiece 200 that is normal after the cutting processing with the camera 30.

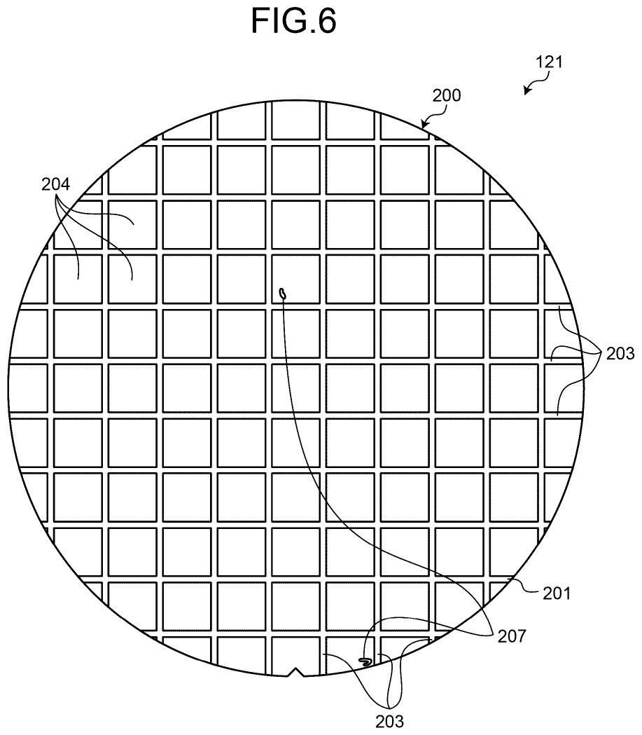

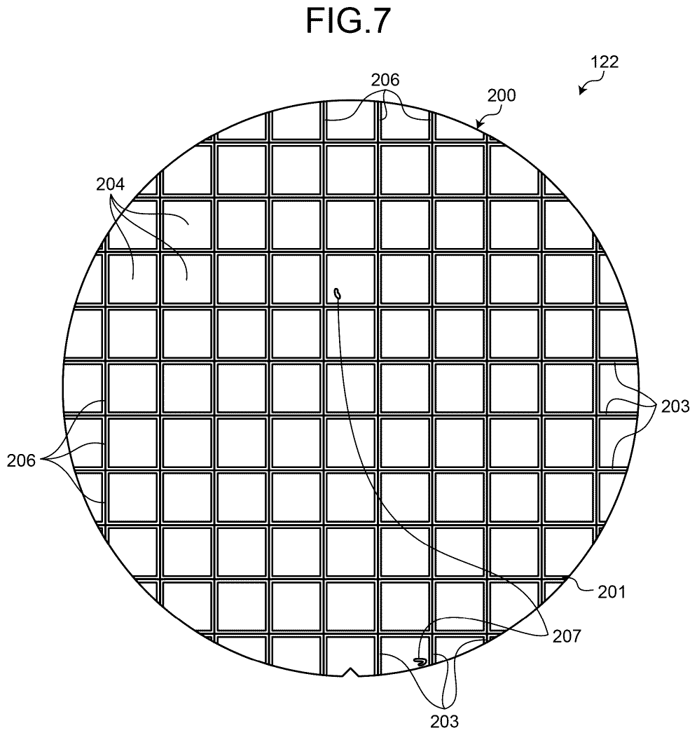

The comparison unit 103 compares a first comparison image 121 (illustrated in FIG. 6 as an example) with the first reference image 111 registered in the registration unit 102. The first comparison image 121 is first detection information obtained by capturing an image of the workpiece 200 with the camera 30 before the workpiece 200 is subjected to cutting processing by the cutting unit 20. The comparison unit 103 also compares a second comparison image 122 (illustrated in FIG. 7 as an example) with the second reference image 112 registered in the registration unit 102. The second comparison image 122 is second detection information obtained by capturing an image of the workpiece 200 with the camera 30 after the workpiece 200 is subjected to cutting processing by the cutting unit 20 and cleaning by the cleaning unit 70.

Note that the function of the registration unit 102 is implemented by the storage device described above. The functions of the processing control unit 101 and the comparison unit 103 are implemented by the arithmetic processing device performing arithmetic processing according to the computer program stored in the storage device.

### Processing Method

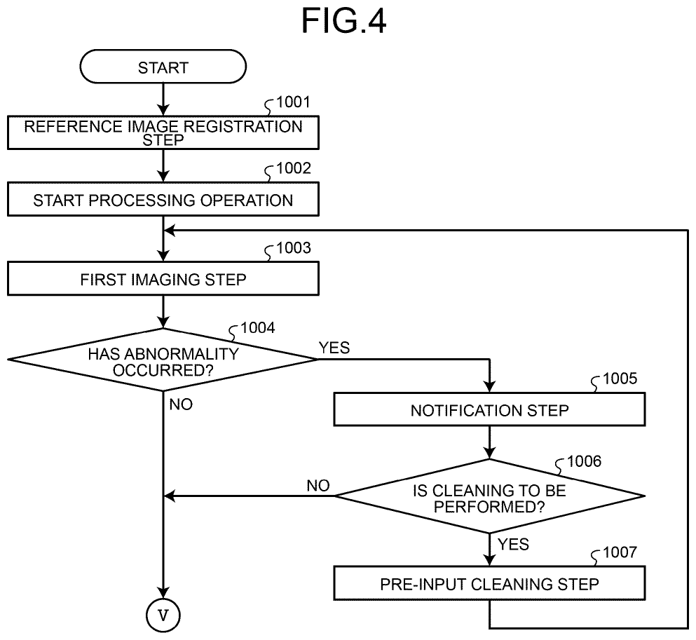

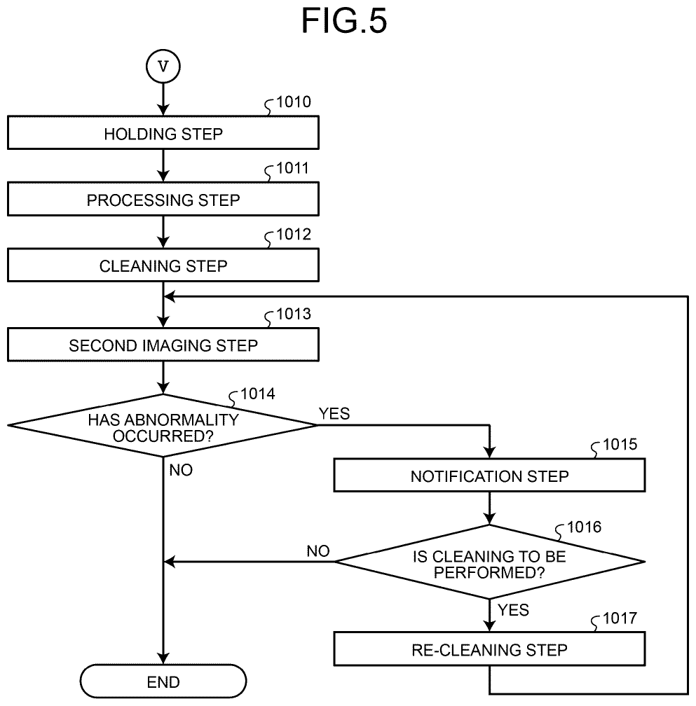

Next, a processing method according to the first embodiment will be described. FIG. 4 is a flowchart illustrating a part of a flow of the processing method according to the first embodiment. FIG. 5 is a flowchart illustrating the other part of the flow of the processing method according to the first embodiment. FIG. 6 is a diagram illustrating an example of a first comparison image generated in a first imaging step of the processing method illustrated in FIG. 4. FIG. 7 is a diagram illustrating an example of a second comparison image generated in a second imaging step of the processing method illustrated in FIG. 5.

The processing method according to the first embodiment is a method in which the processing device 1 performs cutting processing on the planned division lines 203 of the workpiece 200 with the cutting blade to form cutting grooves 206 along division-planned lines 203, and divides the workpiece 200 into individual devices 204. The processing method according to the first embodiment is also a processing operation of the processing device 1 having the above-described configuration.

As illustrated in FIGS. 4 and 5, the processing method according to the first embodiment includes a first imaging step 1003, which is an abnormality detection step, a first comparison step 1004, a holding step 1010, a processing step 1011, a second imaging step 1013, and a second comparison step 1014. In the processing method according to the first embodiment, in a reference image registration step 1001, processing conditions are registered in the control unit 100 by the operator or the like, and the cassette 51 containing the workpiece 200 before cutting processing is placed on the cassette table 50. The processing conditions include a first reference image 111 serving as first reference information and a second reference image 112 serving as second reference information. In the processing method according to the first embodiment, when the control unit 100 of the processing device 1 receives a processing operation start instruction from the operator, a processing operation of the processing device 1 is started (step 1002).

In the processing method according to the first embodiment, when the processing operation is started, the processing device 1 rotates the spindle about the axis at a rotation speed determined by the processing conditions, and performs the first imaging step 1003. The first imaging step 1003 is an abnormality detection step in which the camera 30 images the workpiece 200 to detect an abnormality of the workpiece 200 before the processing step 1011.

In the first imaging step 1003, in the processing device 1, the processing control unit 101 of the control unit 100 controls the conveyance unit 60 to take out the workpiece 200 from the cassette 51 and place the workpiece 200 on the guide rails 61 before cutting processing. In the first imaging step 1003, in the processing device 1, the processing control unit 101 of the control unit 100 controls the camera 30 to image the workpiece 200 placed on the guide rails 61, thereby obtaining a second comparison image 122 illustrated in FIG. 6 as an example. Then, the process proceeds to the first comparison step 1004.

The first comparison step 1004 is a step of, before the processing step 1011 and after the first imaging step 1003, comparing the first reference image 111 registered in the registration unit 102 for determining that the workpiece 200 before cutting processing is normal with the first comparison image 121 newly obtained by imaging the target workpiece 200 before cutting processing in the first imaging step 1003. In the first comparison step 1004, in the processing device 1, the comparison unit 103 of the control unit 100 performs template matching (pattern matching) between the first reference image 111 and the first comparison image 121. As the template matching, for example, known SAD, SSD, NCC, ZNCC, or the like can be used, and these are basically algorithms that look at and determine differences between pixel values in various methods. The comparison unit 103 of the control unit 100 performs pattern matching between the first reference image 111 and the first comparison image 121, and determines whether an abnormality has occurred in the workpiece 200 placed on the guide rails 61 before being subjected to cutting processing based on whether similarity therebetween is equal to or higher than a predetermined value.

In the first comparison step 1004, in the processing device 1, when the similarity is lower than the predetermined value, the comparison unit 103 of the control unit 100 determines that an abnormality has occurred in the workpiece 200 placed on the guide rails 61 before cutting processing (Yes). Then, the process proceeds to the notification step 1005. Since the first comparison image 121 illustrated in FIG. 6 includes two abnormal portions 207, it is determined in the first comparison step 1004 that an abnormality has occurred in the workpiece 200 before cutting processing. The abnormal portion 207 is a portion where a foreign matter is attached onto the front surface 201 of the workpiece 200 or a portion where the front surface 201 of the workpiece 200 is damaged.

The notification step 1005 is a step in which the notification unit 80 notifies the operator that an abnormality has occurred in the target workpiece 200 before cutting processing. In the notification step 1005, in the processing device 1, the processing control unit 101 of the control unit 100 operates the notification unit 80 to notify the operator. In this way, in the notification step 1005, when it is determined that there is an abnormality in the workpiece 200 based on the comparison between the first reference image 111 and the first comparison image 121 by the comparison unit 103, the control unit 100 causes the notification unit 80 to notify that the abnormality has occurred.

After the notification step 1005, in the processing device 1, the processing control unit 101 of the control unit 100 determines whether to perform cleaning on the workpiece 200 placed on the guide rails 61 before cutting processing (step 1006). In the first embodiment, when cleaning has not yet been performed on the workpiece 200 placed on the guide rails 61 before cutting processing, it is determined that cleaning is to be performed on the workpiece 200 placed on the guide rails 61 before cutting processing (step 1006: Yes). Then, the process proceeds to a pre-input cleaning step 1007.

The pre-input cleaning step 1007 is a step in which the cleaning unit 70 cleans the workpiece 200 before cutting processing when an abnormality occurs in the workpiece 200 placed on the guide rails 61 before cutting processing in the immediately preceding first comparison step 1004. In the pre-input cleaning step 1007, the processing control unit 101 of the control unit 100 controls the conveyance unit 60 to convey the workpiece 200 placed on the guide rails 61 before cutting processing to the cleaning unit 70, the cleaning unit 70 cleans the workpiece 200 before cutting processing, and thereafter the workpiece 200 before cutting processing is placed back on the guide rails 61. Then, the process returns to the first imaging step 1003. In this way, in the pre-input cleaning step 1007, when it is determined that there is an abnormality in the workpiece 200 based on the comparison between the first reference image 111 and the first comparison image 121 by the comparison unit 103, the workpiece 200 is cleaned by the cleaning unit 70.

In the first comparison step 1004, in the processing device 1, if the similarity is equal to or higher than the predetermined value, when it is determined that no abnormality has occurred in the workpiece 200 placed on the guide rails 61 before cutting processing (No), or when cleaning has been performed on the workpiece 200 placed on the guide rails 61 before cutting processing in the first embodiment, the comparison unit 103 of the control unit 100 determines not to perform cleaning on the workpiece 200 placed on the guide rails 61 before cutting processing (step 1006: No). Then, the process proceeds to the holding step 1010.

The holding step 1010 is a step in which the holding table 10 holds the workpiece 200. In the holding step 1010, in the processing device 1, the processing control unit 101 of the control unit 100 controls the moving unit to locate the holding table 10 in the loading/unloading region, and causes the conveyance unit 60 to place the workpiece 200 before cutting processing placed on the guide rails 61 onto the holding surface 11 of the holding table 10. In the holding step 1010, the processing device 1 causes the processing control unit 101 of the control unit 100 to suck and hold the back surface 205 of the workpiece 200 onto the holding surface 11 of the holding table 10 and causes the clamp portions 12 to clamp the frame 209. Then, the process proceeds to the processing step 1011.

The processing step 1011 is a step in which the cutting unit 20 performs cutting processing on the workpiece 200 held on the holding table 10. In the processing step 1011, in the processing device 1, the processing control unit 101 of the control unit 100 controls the moving unit to move the holding table 10 toward the processing region, the alignment camera 40 captures an image of the workpiece 200, and alignment is performed based on the image captured and obtained by the alignment camera 40.

In the processing step 1011, in the processing device 1, the processing control unit 101 of the control unit 100 controls the moving unit, the cutting unit 20, and so on to cause the cutting edge of the cutting blade to cut into the workpiece 200 until reaching the tape 210 while relatively moving the cutting edge of the cutting blade rotating about the axis of the cutting unit 20 along the planned division lines 203 of the workpiece 200 held on the holding table 10, thereby performing cutting processing on all the planned division lines 203 of the workpiece 200. In the processing step 1011, in the processing device 1, when cutting processing is performed on all the planned division lines 203 of the workpiece 200, the process proceeds to the cleaning step 1012.

The cleaning step 1012 is a step in which the cleaning unit 70 cleans the workpiece 200 subjected to cutting processing in the processing step 1011. In the cleaning step 1012, in the processing device 1, the processing control unit 101 of the control unit 100 controls the moving unit to move the holding table 10 to the loading/unloading region so that the cutting unit is spaced away from the workpiece 200 held on the holding table 10. In the cleaning step 1012, in the processing device 1, the processing control unit 101 of the control unit 100 stops the sucking and holding of the workpiece 200 onto the holding table 10, and releases the clamping of the frame 209 by the clamp portions 12.

In the cleaning step 1012, in the processing device 1, the processing control unit 101 of the control unit 100 controls the conveyance unit 60 to convey the workpiece 200 placed on the holding surface 11 of the holding table 10 in the loading/unloading region after cutting processing to the cleaning unit 70, and the cleaning unit 70 cleans the workpiece 200 after cutting processing. Then, the process proceeds to the second imaging step 1013. The second imaging step 1013 is a step in which the camera 30 images the workpiece 200 after the processing step 1011.

In the second imaging step 1013, in the processing device 1, the processing control unit 101 of the control unit 100 controls the conveyance unit 60 to place the workpiece 200 subjected to cutting processing on the guide rails 61 from the cleaning unit 70. In the second imaging step 1013, in the processing device 1, the processing control unit 101 of the control unit 100 controls the camera 30 to image the workpiece 200 placed on the guide rails 61, thereby obtaining a second comparison image 122 illustrated in FIG. 7 as an example. Then, the process proceeds to the second comparison step 1014.

The second comparison step 1014 is a step of, after the processing step 1011, comparing the second reference image 112 registered in the registration unit 102 for determining that the workpiece 200 after cutting processing is normal with the second comparison image 122 newly obtained by imaging the target workpiece 200 after cutting processing in the second imaging step 1013. In the second comparison step 1014, in the processing device 1, the comparison unit 103 of the control unit 100 performs pattern matching such as normalized correlation between the second reference image 112 and the second comparison image 122, and determines whether an abnormality has occurred in the workpiece 200 placed on the guide rails 61 after cutting processing based on whether similarity therebetween is equal to or higher than the predetermined value.

In the second comparison step 1014, in the processing device 1, when the similarity is lower than the predetermined value, the comparison unit 103 of the control unit 100 determines that an abnormality has occurred in the workpiece 200 placed on the guide rails 61 after cutting processing (Yes). Then, the process proceeds to the notification step 1015. Since the second comparison image 122 illustrated in FIG. 7 includes two abnormal portions 207, it is determined in the second comparison step 1014 that an abnormality has occurred in the workpiece 200 after cutting processing.

The notification step 1015 is a step in which the notification unit 80 notifies the operator that an abnormality has occurred in the target workpiece 200 after cutting processing. In the notification step 1015, in the processing device 1, the processing control unit 101 of the control unit 100 operates the notification unit 80 to notify the operator. In this way, in the notification step 1015, when it is determined that there is an abnormality in the workpiece 200 based on the comparison between the second reference image 112 and the second comparison image 122 by the comparison unit 103, the control unit 100 causes the notification unit 80 to notify that the abnormality has occurred.

After the notification step 1015, in the processing device 1, the processing control unit 101 of the control unit 100 determines whether to perform cleaning on the workpiece 200 placed on the guide rails 61 after cutting processing (step 1016). In the first embodiment, when cleaning has not yet been performed on the workpiece 200 placed on the guide rails 61 after cutting processing after the cleaning step, it is determined that cleaning is to be performed on the workpiece 200 placed on the guide rails 61 after cutting processing (step 1016: Yes), and the process proceeds to the re-cleaning step 1017.

The re-cleaning step 1017 is a step in which the cleaning unit 70 cleans the workpiece 200 after cutting processing when an abnormality occurs in the workpiece 200 placed on the guide rails 61 after cutting processing in the immediately preceding second comparison step 1014. In the re-cleaning step 1017, the processing control unit 101 of the control unit 100 controls the conveyance unit 60 to convey the workpiece 200 placed on the guide rails 61 after cutting processing to the cleaning unit 70, the cleaning unit 70 cleans the workpiece 200 after cutting processing, and thereafter the workpiece 200 after cutting processing is placed back on the guide rails 61. Then, the process returns to the second imaging step 1013. In this way, in the re-cleaning step 1017, when it is determined that there is an abnormality in the workpiece 200 based on the comparison between the second reference image 112 and the second comparison image 122 by the comparison unit 103, the workpiece 200 is cleaned by the cleaning unit 70.

In the second comparison step 1014, in the processing device 1, if the similarity is equal to or higher than the predetermined value, when it is determined that no abnormality has occurred in the workpiece 200 placed on the guide rails 61 after cutting processing (No), or when cleaning has been performed on the workpiece 200 placed on the guide rails 61 after cutting processing after the cleaning step 1012 in the first embodiment, the comparison unit 103 of the control unit 100 determines not to perform cleaning on the workpiece 200 placed on the guide rails 61 after cutting processing (step 1016: No), and the processing control unit 101 of the control unit 100 controls the conveyance unit 60 to accommodate the workpiece 200 after cutting processing in the cassette 51. The processing device 1 sequentially performs cutting processing on the workpieces 200 in the cassette 51, and terminates the processing operation when the cutting processing is completed on the workpieces 200 in the cassette 51.

As described above, the processing device 1 according to the first embodiment includes: a control unit 100 including the registration unit 102 that registers a first reference image 111 for determining the workpiece 200 before cutting processing to be normal in advance; and a comparison unit 103 that compares the first reference image 111 registered in the registration unit 102 with a first comparison image 121 newly obtained by imaging the workpiece 200 with the camera 30 before the workpiece 200 is subjected to cutting processing by the cutting unit 20.

Therefore, the processing device 1 and the processing method according to the first embodiment is capable of determining whether there is an abnormality in the front surface 201 of the workpiece 200 before being subjected to cutting processing by the cutting unit 20.

As a result, the processing device 1 and the processing method according to the first embodiment have an effect in that it is possible to specify whether the abnormality of the workpiece 200 has been caused by a defect of the processing device 1.

### Second Embodiment

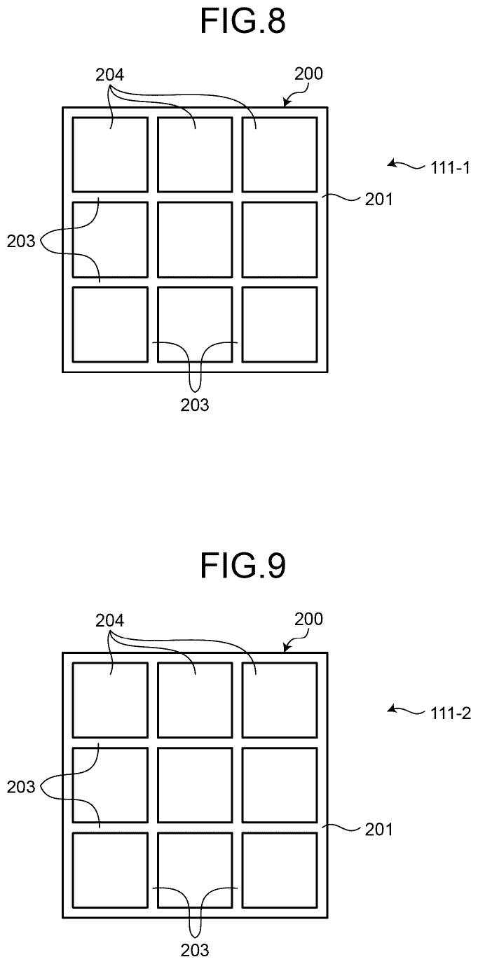

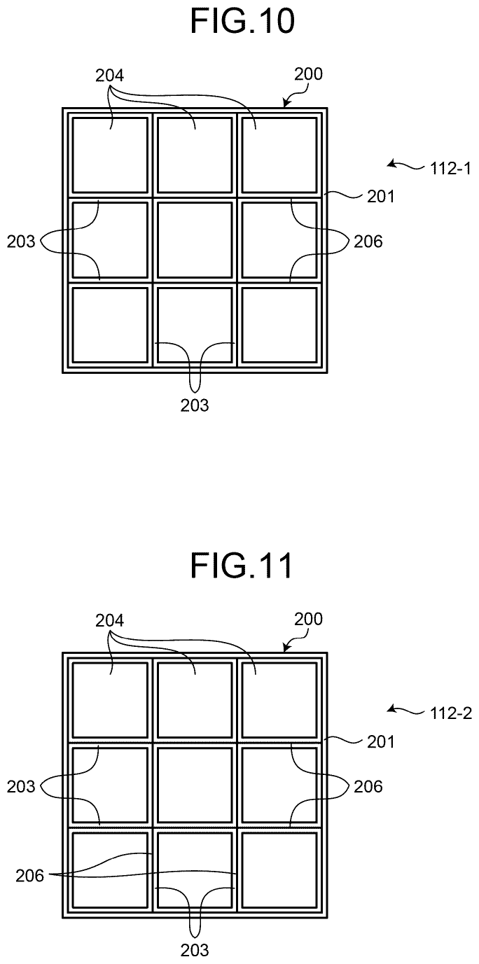

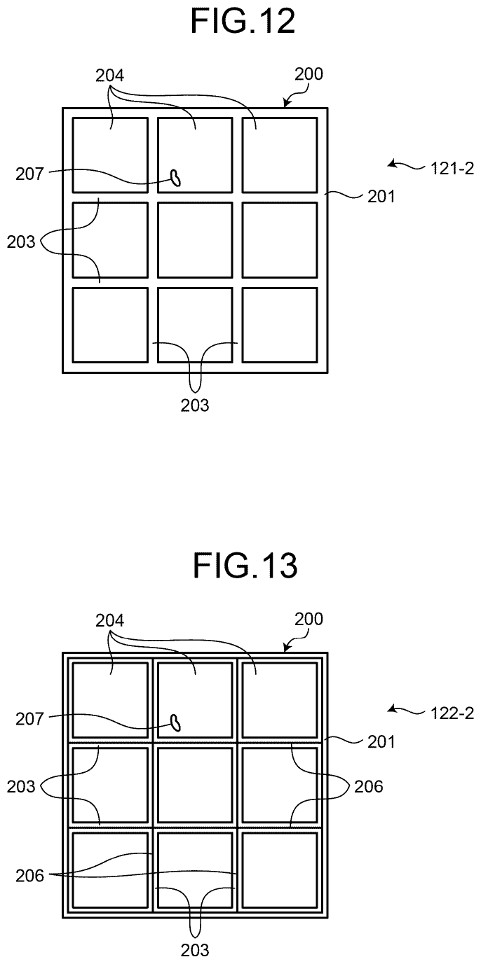

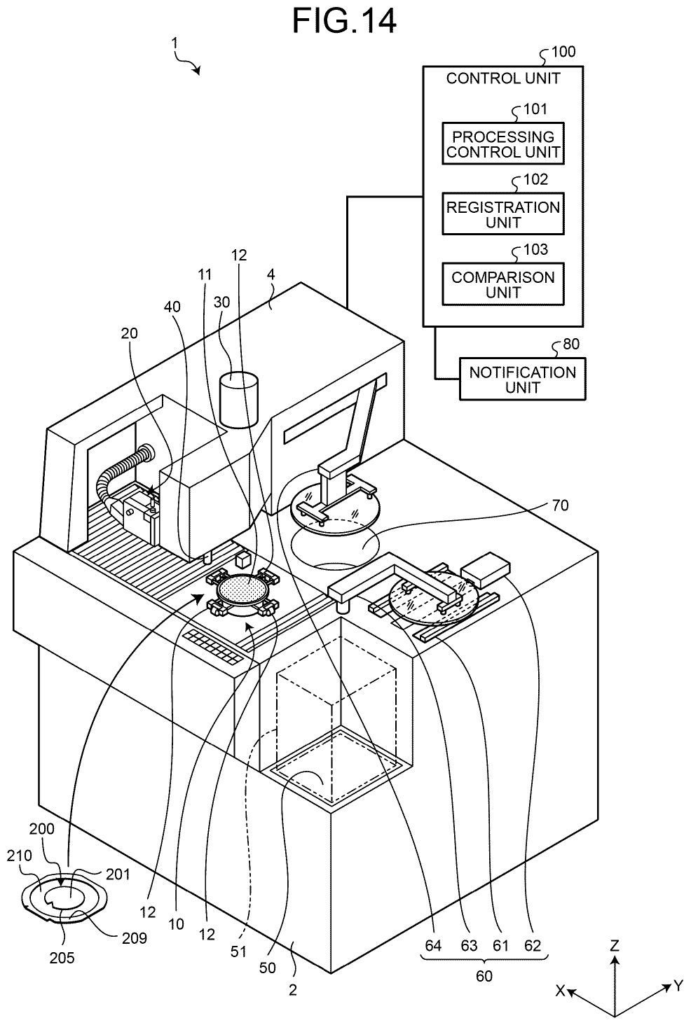

A processing device and a processing method according to a second embodiment will be described with reference to the drawings. FIG. 8 is a diagram illustrating an example of a first reference image registered in a registration unit of a control unit of the processing device according to the second embodiment. FIG. 9 is a diagram illustrating another example of a first reference image registered in the registration unit of the control unit of the processing device according to the second embodiment. FIG. 10 is a diagram illustrating an example of a second reference image registered in the registration unit of the control unit of the processing device according to the second embodiment. FIG. 11 is a diagram illustrating another example of a second reference image registered in the registration unit of the control unit of the processing device according to the second embodiment. FIG. 12 is a diagram illustrating an example of a first comparison image generated in a first imaging step according to the second embodiment. FIG. 13 is a diagram illustrating an example of a second comparison image generated in a second imaging step of the processing method according to the second embodiment. In FIGS. 8, 9, 10, 11, 12, and 13, the same parts as those in the first embodiment are denoted by the same reference numerals, and description thereof is omitted.

The processing device 1 according to the second embodiment is the same as that according to the first embodiment, except that first reference images 111-1 and 111-2 that are reference information illustrated in FIGS. 8 and 9 and second reference images 112-1 and 112-2 that are reference information illustrated in FIGS. 10 and 11, which are registered in the registration unit 102, are different, and the alignment camera 40, which is an abnormality detection unit, images the front surface 201 of the workpiece 200 held on the holding surface 11 of the holding table 10 to detect abnormalities in the workpiece 200 in the imaging steps 1003 and 1013.

In the second embodiment, the first reference images 111-1 and 111-2 are images of partial region between which similarity is equal to or higher than a threshold, among a plurality of images of partial regions obtained by imaging at least two partial regions in the front surface 201 of the workpiece 200 determined to be normal before cutting processing with the alignment camera 40. In the second embodiment, the first reference images 111-1 and 111-2 are two images of partial regions having the highest similarity when pattern matching is performed on a plurality of images of partial regions obtained by imaging at least two partial regions in the front surface 201 of the workpiece 200 determined to be normal before cutting processing with the alignment camera 40.

In the second embodiment, the second reference images 112-1 and 112-2 are images of partial regions between which similarity is more equal to or higher than a threshold, among a plurality of images of partial regions obtained by imaging at least two partial regions in the front surface 201 of the workpiece 200 determined to be normal after cutting processing with the alignment camera 40. In the second embodiment, the second reference images 112-1 and 112-2 are two images of partial regions having the highest similarity when pattern matching such as normalized correlation is performed on a plurality of images of partial regions obtained by imaging at least two partial regions in the front surface 201 of the workpiece 200 determined to be normal after cutting processing with the alignment camera 40.

In the processing method according to the second embodiment, in the first imaging step 1003, the alignment camera 40 images a partial region in the front surface 201 of the target workpiece 200 before cutting processing, thereby obtaining a first comparison image 121-2 illustrated in FIG. 12 as an example. In the processing method according to the second embodiment, in the second imaging step 1013, the alignment camera 40 images a partial region in the front surface 201 of the target workpiece 200 after cutting processing, thereby obtaining a second comparison image 122-2 illustrated in FIG. 13 as an example.

In the processing method according to the second embodiment, in the first comparison step 1004, when the similarity between both the first reference images 111-1 and 111-2 and the first comparison image 121-2 is equal to or higher than the predetermined value, the comparison unit 103 of the control unit 100 determines that no abnormality has occurred in the workpiece 200 held on the holding table 10 before cutting processing (No). In the processing method according to the second embodiment, in the first comparison step 1004, when the similarity between at least one of the first reference images 111-1 and 111-2 and the first comparison image 121-2 is lower than the predetermined value, the comparison unit 103 of the control unit 100 determines that an abnormality has occurred in the workpiece 200 held on the holding table 10 before cutting processing (Yes).

In the processing method according to the second embodiment, in the second comparison step 1014, when the similarity between both the second reference images 112-1 and 112-2 and the second comparison image 122-2 is equal to or higher than the predetermined value, the comparison unit 103 of the control unit 100 determines that no abnormality has occurred in the workpiece 200 held on the holding table 10 after cutting processing (No). In the processing method according to the second embodiment, in the second comparison step 1014, when the similarity between at least one of the second reference images 112-1 and 112-2 and the second comparison image 122-2 is lower than the predetermined value, the comparison unit 103 of the control unit 100 determines that an abnormality has occurred in the workpiece 200 held on the holding table 10 after cutting processing (Yes).

Since each of the first comparison image 121-2 illustrated in FIG. 12 and the second comparison image 122-2 illustrated in FIG. 13 includes one abnormal portion 207, it is determined in the first and second comparison steps 1004 and 1014 that an abnormality has occurred in the workpiece 200 before and after cutting processing. As such, the first comparison image 121-2 and the second comparison image 122-2 are images of a partial region obtained by imaging the partial region of the front surface 201 of the target workpiece 200 before and after cutting processing.

The processing device 1 according to the second embodiment includes a control unit 100 including: a registration unit 102 that registers the first reference images 111-1 and 111-2; and a comparison unit 103 that compares the first reference images 111-1 and 111-2 with the first comparison image 121-2 newly obtained by imaging the workpiece 200 with the camera 30 before the workpiece 200 is subjected to cutting processing by the cutting unit 20. Thus, the processing device 1 according to the second embodiment has an effect in that it is possible to determine whether there is an abnormality in the front surface 201 of the workpiece 200 before being subjected to cutting processing by the cutting unit 20, and it is possible to specify whether the abnormality of the workpiece 200 is caused by a defect of the processing device 1 as in the first embodiment.

Note that the present invention is not limited to the above-described embodiment. That is, various modifications can be made without departing from the gist of the present invention. In the present invention, as illustrated in FIG. 14, the camera 30 may be disposed above the holding surface 11 of the holding table 10 in the loading/unloading region in the Z-axis direction and provided on the conveyance path of the workpiece 200. FIG. 14 is a perspective view illustrating a modification of the processing device illustrated in FIG. 1, and the same parts as those in the first embodiment are denoted by the same reference numerals, and description thereof is omitted.

Further, in the present invention, the alignment camera 40 may image a plurality of areas of the front surface 201 of the workpiece 200 held on the holding surface 11 of the holding table 10 to generate reference images 111 and 112 and comparison images 121 and 122 for the entire front surface 201 of the workpiece 200.

Further, in the present invention, in the processing device 1, at least one of the first reference image (111; 111-1, 111-2) and the second reference image (112; 112-1, 112-2) may be the first comparison image (121; 121-2) or the second comparison image (122; 122-2) obtained in the previous imaging step 1003 or 1013. In this case, the first comparison image (121; 121-2) and the second comparison image (122; 122-2) determined that no abnormality has occurred in the previous comparison steps 1004 and 1014 are updated to the first reference image (111; 111-1, 111-2) or the second reference image (112; 112-1, 112-2).

Further, in the present invention, the processing device 1 is not limited to the cutting device that performs cutting processing on the workpiece 200, and may be any of various processing devices such as a laser processing device that performs laser processing on the workpiece 200, a grinding device that performs grinding processing on the workpiece 200, or a polishing device that performs polishing processing on the workpiece 200.

In the present invention, the abnormality detection unit may be a particle counter that detects particles of the workpiece 200 or a thickness detection sensor that measures the thickness of the workpiece 200. In this case, reference information is a reference threshold (number) or a reference thickness, and detection information is a number or a thickness.

In addition, in the present invention, in a case where the abnormality detection unit is the camera 30, an image may be captured while applying oblique illumination with narrowed-down light at an LED-UV wavelength to the workpiece 200. Note that, the narrowing-down of the light means that strong light is generated in one direction, like polarion light, making it easier to find a small object. The use of the UV wavelength leads to emission of light of fluorescent substances, thereby forming an LED-UV light source, which has a spectral output with a narrow UV wavelength (short wavelength), making the light more likely to scatter. The short wavelength are suitable when light is applied to a minute object such as dust or foreign matter and reflected.

In the present invention, the pre-input cleaning step 1007 and the re-cleaning step 1017 may be modified to be performed under a cleaning condition having a stronger cleaning power as compared with the cleaning condition of the cleaning step 1012 after cutting processing is performed on the workpiece 200. For example, the cleaning unit 70 that supplies pure water at a high pressure (0.2 MPa (gauge pressure) or more and 0.5 MPa (gauge pressure) or less) to perform cleaning may supply the high-pressure pure water for 60 seconds to perform cleaning under the cleaning condition for the cleaning step 1012, and the cleaning condition for the pre-input cleaning step 1007 and the re-cleaning step 1017 may be changed to a cleaning condition that extends the cleaning time to 120 seconds, which is twice as long as the cleaning condition after cutting processing.

The present invention has an effect in that it is possible to specify whether or not an abnormality of a workpiece is caused by a defect of a processing device.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A processing device for processing a workpiece, the processing device comprising:
a holding table that holds the workpiece;
a processing unit that performs processing on the workpiece held on the holding table;
an abnormality detection unit that detects an abnormality of the workpiece; and
a control unit that controls at least the processing unit and the abnormality detection unit,
wherein the control unit includes:
a registration unit that registers first reference information serving as a reference for determining that the workpiece before processing is normal; and
a comparison unit that compares the first reference information registered in the registration unit with first detection information obtained by detecting the workpiece by the abnormality detection unit before the workpiece is processed by the processing unit.

2. The processing device according to claim 1, wherein
the registration unit of the control unit registers second reference information serving as a reference for determining that the workpiece after processing is normal;
the comparison unit of the control unit compares the second reference information registered in the registration unit with second detection information obtained by detecting the workpiece by the abnormality detection unit after the workpiece is processed by the processing unit.

3. The processing device according to claim 1, further comprising a notification unit,
wherein when it is determined that there is an abnormality in the workpiece based on the comparison by the comparison unit, the control unit causes the notification unit to notify that the abnormality has occurred.

4. The processing device according to claim 1, further comprising a cleaning unit that cleans the workpiece,
wherein when it is determined that there is an abnormality in the workpiece based on the comparison by the comparison unit, the control unit causes the cleaning unit to clean the workpiece.

5. The processing device according to claim 1, further comprising:
a cassette table on which a cassette containing the workpiece is placed; and
a conveyance unit that conveys the workpiece from the cassette placed on the cassette table to the holding table,
wherein the abnormality detection unit is disposed on a conveyance path along which the workpiece is conveyed from the cassette to the holding table by the conveyance unit.

6. The processing device according to claim 2, wherein at least one of the first reference information and the second reference information is previous first detection information or previous second detection information obtained by previous detection by the abnormality detection unit.

7. The processing device according to claim 1, wherein
the abnormality detection unit is a camera that images the workpiece,
the first reference information is images of partial regions between which similarity is equal to or higher than a threshold, among a plurality of images of partial regions obtained by imaging at least two partial regions in the workpiece using the camera, and
the first detection information is an image of a partial region obtained by imaging the partial region of the workpiece with the camera.

8. A processing method for processing a workpiece, the processing method comprising:
holding the workpiece on a holding table;
performing processing on the workpiece held on the holding table by a processing unit;
detecting an abnormality of the workpiece before performing the processing; and
before performing the processing and after detecting the abnormality of the workpiece, comparing reference information registered for determining that the workpiece before processing is normal with detection information obtained by newly detecting the workpiece in detecting the abnormality.
